(19) United States
(12) Patent Application Publication
(10) Pub. No.: US 2013/0240013 A1
(43) Pub. Date: Sep. 19, 2013

(54) PHOTOVOLTAIC POWER GENERATION MODULE, PHOTOVOLTAIC POWER GENERATION MODULE ARRAY, AND MOBILE UNIT

(71) Applicant: SHARP KABUSHIKI KAISHA, Osaka (JP)

(72) Inventors: Yoshifumi Yaoi, Osaka (JP); Kohtaroh Kataoka, Osaka (JP); Kohichiroh Adachi, Osaka (JP); Masatomi Harada, Osaka (JP); Yoshiji Ohta, Osaka (JP); Hiroshi Iwata, Osaka (JP)

(73) Assignee: Sharp Kabushiki Kaisha, Osaka (JP)

(21) Appl. No.: 13/834,776

(22) Filed: Mar. 15, 2013

(30) Foreign Application Priority Data
Mar. 16, 2012 (JP) 2012-060902

(51) Int. Cl. H01L 31/05

(52) U.S. Cl. CPC H01L 31/0504
USPC 136/244

(57) ABSTRACT

A photovoltaic power generation module includes: a plurality of rectangular photovoltaic power generation elements that are arranged such that long sides of perimeters of the elements are parallel; and an extension wiring that is extended in a short side direction intersecting the long sides and that interconnects the photovoltaic power generation elements, and the extension wiring connects every specified number of the photovoltaic power generation elements in parallel.

### CROSS-REFERENCE TO RELATED APPLICATION

This application claims priority under 35 U.S.C. §119 (a) on Patent Application No. 2012-60902 filed in Japan on Mar. 16, 2012, the entire contents of which are herein incorporated by reference.

### BACKGROUND OF THE INVENTION

1. Field of the Invention

The present invention relates to a photovoltaic power generation module in which rectangular photovoltaic power generation elements are arranged in parallel, a photovoltaic power generation module array in which such photovoltaic power generation modules are connected, and a mobile unit including such a photovoltaic power generation module.

2. Description of the Related Art

Solar cells having an elongated cell shape are known, and such solar cells are arranged in parallel in one direction in a solar cell module. In the case where solar cell modules are arranged in parallel in a direction intersecting the lengthwise direction of the solar cell modules such that the lengthwise direction of the solar cell modules and the lengthwise direction of solar cells match, a situation can occur in which the output power of the solar cells and the solar cell modules is reduced due to a shadow caused by a difference between adjacent solar cell modules.

As a countermeasure against the shadow, a technique has been proposed in which solar cells are arranged such that the lengthwise direction of the solar cells is parallel to the lengthwise direction of the solar cell module (see, for example, JP 2001-111083A (hereinafter referred to as Patent Document 1)).

However, the technique disclosed in Patent Document 1 merely suppresses the influence of the shadow caused by the photovoltaic power generation modules that are simply arranged adjacent to each other, and does not take any measures when a so-called shade falls on the solar cells. For this reason, the technique is problematic in that the influence of the shade on the solar cell modules that use solar cells having an elongated shape is not eliminated.

Particularly, for the solar cells (solar cell modules) applied to applications, such as mobile units, in which the shade exerts a large influence, the countermeasure against the shade is the key issue.

The present invention has been made under the above circumstances, and it is an object of the present invention to provide a photovoltaic power generation module that suppresses a reduction in the amount of power generation due to the shade and improves power extraction efficiency by including extension wiring that is disposed so as to extend in a short side direction intersecting the long sides of a plurality of rectangular photovoltaic power generation elements arranged such that the long sides of the perimeters of the elements are parallel to each other, the extension wiring connecting every specified number of photovoltaic power generation elements in parallel, and connecting in parallel the photovoltaic power generation elements arranged in parallel in one dimensional direction while the photovoltaic power generation elements are arranged in a distributed manner.

Also, it is another object of the present invention to provide a photovoltaic power generation module array that is capable of a large amount of photovoltaic power generation with excellent shade resistance and good power extraction efficiency, by including a plurality of the photovoltaic power generation modules according to the present invention.

Also, it is another object of the present invention to provide a mobile unit that suppresses a reduction in the amount of power generation due to the shade, improves power extraction efficiency and is capable of stable photovoltaic power generation even when the mobile unit is moving, by including the photovoltaic power generation module according to the present invention.

### SUMMARY OF THE INVENTION

A photovoltaic power generation module according to the present invention includes: a plurality of rectangular photovoltaic power generation elements that are arranged such that long sides of perimeters of the elements are parallel; and an extension wiring that is extended in a short side direction intersecting the long sides and that interconnects the photovoltaic power generation elements, wherein the extension wiring connects every specified number of the photovoltaic power generation elements in parallel.

Accordingly, because the photovoltaic power generation module according to the present invention includes the extension wiring that is disposed so as to extend in a short side direction intersecting the long sides of the photovoltaic power generation elements and that connects every specified number of photovoltaic power generation elements in parallel, the rectangular photovoltaic power generation elements arranged in parallel in one dimensional direction can be connected in parallel while the photovoltaic power generation elements are arranged in a distributed manner, as a result of which a reduction in the amount of power generation due to the shade is suppressed, and power extraction efficiency is improved.

Also, in the photovoltaic power generation module according to the present invention, the photovoltaic power generation elements may include a first electrode of a first polarity that is disposed on a first side in the short side direction and a second electrode of a second polarity that is disposed on a second side in the short side direction.

Accordingly, in the photovoltaic power generation module according to the present invention, a first electrode having a first polarity and a second electrode having a second polarity are disposed along the extension wiring, and therefore the photovoltaic power generation elements and the extension wiring can be easily connected.

Also, in the photovoltaic power generation module according to the present invention, the first electrode and the second electrode may be extended along the long sides respectively.

Accordingly, in the photovoltaic power generation module according to the present invention, connection between the extension wiring and the first electrode and connection between the extension wiring and the second electrode can be made easily and reliably. Also, it is possible to easily collect current over a wide range along the long sides.

Also, the photovoltaic power generation module according to the present invention may include a series section in which a group of the photovoltaic power generation elements are connected in series.

Accordingly, because the photovoltaic power generation module according to the present invention includes a series section in which a group of photovoltaic power generation elements are connected in series, a plurality of series sections can be easily formed along the extension wiring, and thus parallel connection of the series stages of each series section can be easily achieved.

Also, in the photovoltaic power generation module according to the present invention, the series section may be formed by the photovoltaic power generation elements that are adjacent to each other.

Accordingly, in the photovoltaic power generation module according to the present invention, because the series section is formed by connecting in series a group of photovoltaic power generation elements that are adjacent to each other, it is possible to easily form a plurality of series sections along the extension wiring.

Also, in the photovoltaic power generation module according to the present invention, with respect to the photovoltaic power generation elements arranged in the series section, an arrangement order in series stages in the series section and an arrangement order in a layout pattern in the series section may be the same.

Accordingly, in the photovoltaic power generation module according to the present invention, with respect to the photovoltaic power generation elements arranged in the series section, an arrangement order in series stages in the series section and an arrangement order in a layout pattern in the series section are matched, and therefore parallel connections between a plurality of series sections along the extension wiring are easily achieved with a simple wiring structure. Also, the photovoltaic power generation elements connected in the same series stage are arranged in a distributed manner, and therefore shade resistance can be reliably improved, and a cost reduction can be achieved.

Also, in the photovoltaic power generation module according to the present invention, with respect to the photovoltaic power generation elements arranged in the series section, an arrangement order in series stages in the series section and an arrangement order in a layout pattern in the series section may be different.

Accordingly, in the photovoltaic power generation module according to the present invention, with respect to the photovoltaic power generation elements arranged in the series section, an arrangement order in series stages in the series section and an arrangement order in a layout pattern in the series section are made different, and therefore the degree of distribution of the photovoltaic power generation elements that are connected in the same series stage is further improved, and thus the shade resistance is further improved.

Also, the photovoltaic power generation module according to the present invention may include cross wiring that interconnects the extension wiring mutually.

Accordingly, because the photovoltaic power generation module according to the present invention includes cross wiring that interconnects the extension wiring, the arrangement order in the series stages of the photovoltaic power generation elements arranged in the series sections can be freely set by forming a current path between wires of the extension wiring, as a result of which the degree of distribution of the photovoltaic power generation elements can be improved easily and reliably.

Also, a photovoltaic power generation module array according to the present invention includes a plurality of photovoltaic power generation modules, and the photovoltaic power generation modules are photovoltaic power generation modules according to the present invention.

Accordingly, because the photovoltaic power generation module array according to the present invention includes a plurality of photovoltaic power generation modules according to the present invention, a large amount of photovoltaic power generation with excellent shade resistance and good power extraction efficiency is possible.

Also, in the photovoltaic power generation module array according to the present invention, the photovoltaic power generation modules may be connected in parallel.

Accordingly, in the photovoltaic power generation module array according to the present invention, because the photovoltaic power generation modules are connected in parallel, the photovoltaic power generation module array can generate a large current while shade resistance is improved.

Also, in the photovoltaic power generation module array according to the present invention, the photovoltaic power generation modules may be connected in series.

Accordingly, in the photovoltaic power generation module array according to the present invention, because the photovoltaic power generation modules are connected in series, the photovoltaic power generation module array can generate a high voltage while shade resistance is improved.

A mobile unit according to the present invention includes a photovoltaic power generation module in which a plurality of photovoltaic power generation elements are connected, and the photovoltaic power generation module is a photovoltaic power generation module according to the present invention.

Accordingly, because the mobile unit according to the present invention incorporates a photovoltaic power generation module according to the present invention, a reduction in the amount of power generation due to the shade is suppressed, and power extraction efficiency is improved, as result of which stable photovoltaic power generation is possible even when the mobile unit is moving.

### BRIEF DESCRIPTION OF THE DRAWINGS

FIG. 1A is a schematic plan view schematically showing the relationship between a layout pattern of photovoltaic power generation elements and extension wiring in a photovoltaic power generation module according to Embodiment 1 of the present invention.

FIG. 1B is a schematic connection diagram schematically showing the connection relationship between the photovoltaic power generation elements and the extension wiring in the photovoltaic power generation module shown in FIG. 1A.

FIG. 2A is a schematic plan view schematically showing a layout pattern in a photovoltaic power generation module according to a conventional configuration for comparison to illustrate the action of the photovoltaic power generation module shown in FIG. 1A.

FIG. 2B is a schematic diagram of a shade illustrating the state of a shade falling on two types of photovoltaic power generation modules that are compared (a photovoltaic power generation module according to the present invention and a photovoltaic power generation module according to a conventional configuration).

FIG. 2C is a graph showing the output power characteristics of the two types of photovoltaic power generation modules compared in terms of variations in the output power due to the shade.

FIG. 3A is a schematic plan view schematically showing the relationship between a layout pattern of photovoltaic power generation elements and extension wiring in a photovoltaic power generation module according to Embodiment 2 of the present invention.

FIG. 3B is a schematic connection diagram schematically showing the connection relationship between the photovoltaic power generation elements and the extension wiring in the photovoltaic power generation module shown in FIG. 3A.

FIG. 4A is a schematic plan view schematically showing a connection state (parallel connection) of photovoltaic power generation modules in a photovoltaic power generation module array according to Embodiment 3 of the present invention.

FIG. 4B is a schematic plan view schematically showing a connection state (series connection) of photovoltaic power generation modules in a photovoltaic power generation module array according to Embodiment 3 of the present invention.

FIG. 5 is a schematic diagram schematically showing the overall view of a mobile unit according to Embodiment 4 of the present invention.

### DESCRIPTION OF REFERENCE NUMERALS

1 Photovoltaic power generation module
1A Photovoltaic power generation module array
101p Mounting unit
10, 11, . . . Photovoltaic power generation element
20, 21, . . . Extension wiring
30, 31, 32 Series section
40, 41, . . . Cross wiring
45 Series wiring
46 Parallel wiring
50 Mobile unit
51 Power converting unit
52 Power storage unit
LS Long side
Lsc Effective length
Lss Illumination length
SH Shade
SS Short side
T1 First electrode
T2 Second electrode
Xd Short side direction

### DESCRIPTION OF THE PREFERRED EMBODIMENT

Hereinafter, embodiments of the present invention will be described with reference to the drawings.

### Embodiment 1

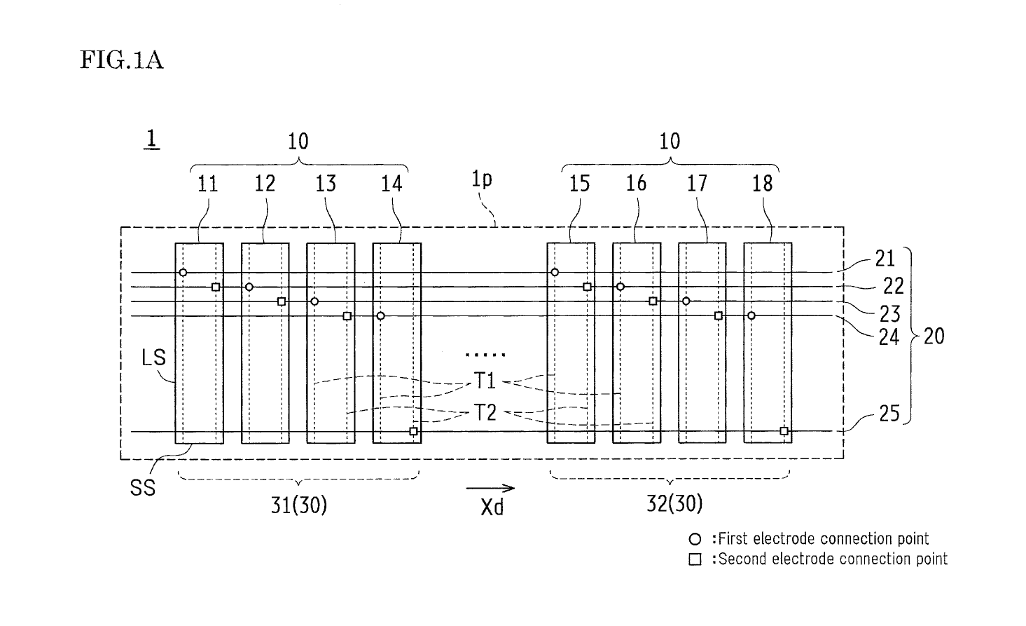

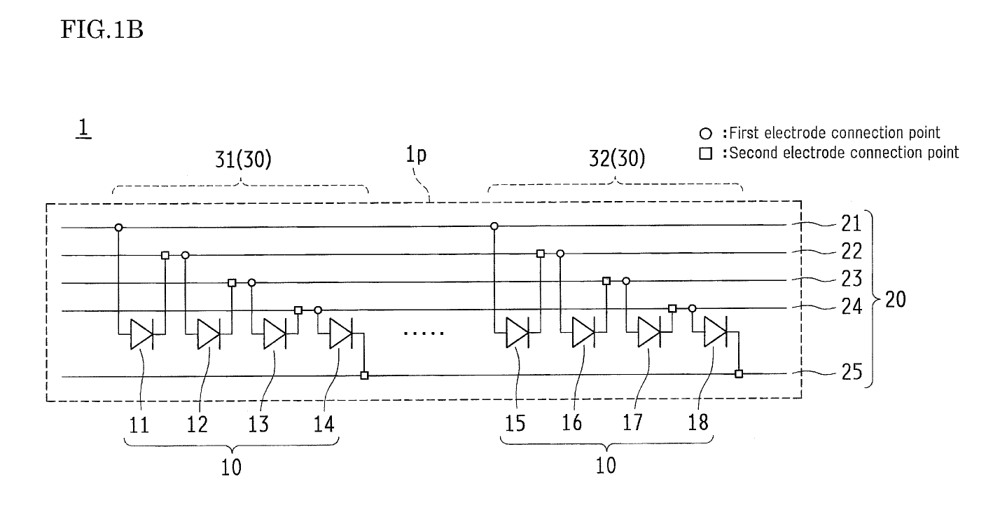

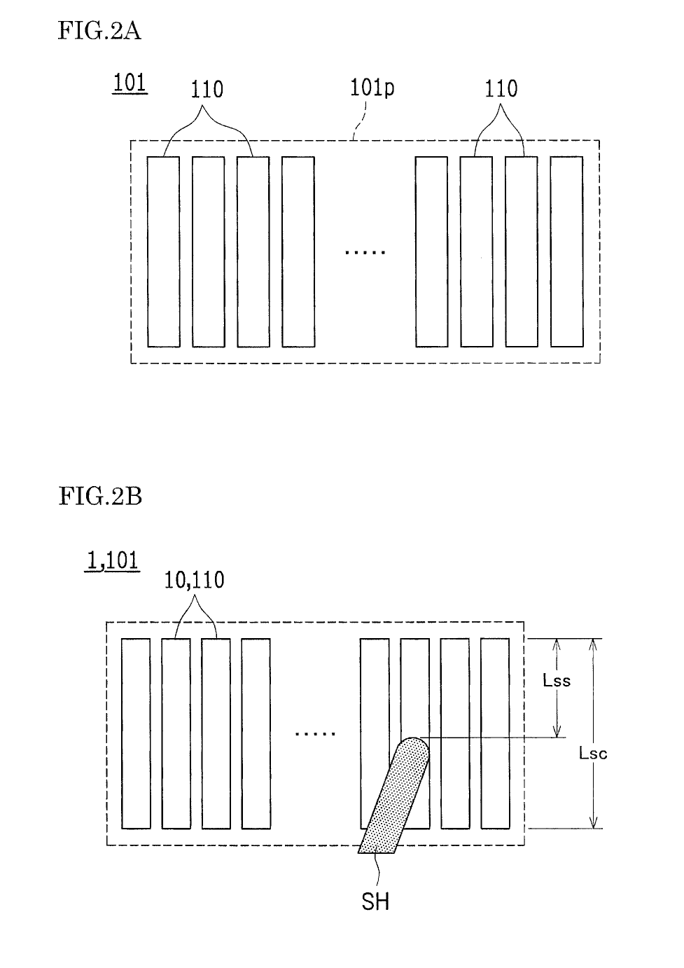

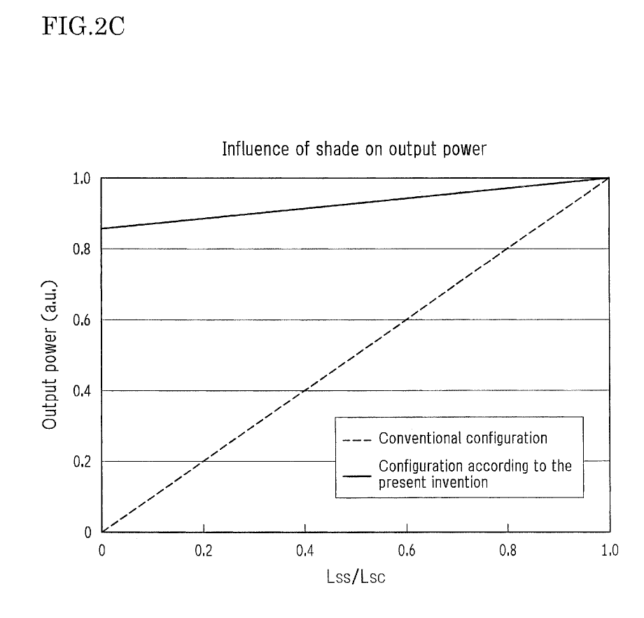

A photovoltaic power generation module 1 according to the present invention will be described with reference to FIGS. 1A to 2C.

FIG. 1A is a schematic plan view schematically showing the relationship between a layout pattern of photovoltaic power generation elements 10 and extension wiring 20 in a photovoltaic power generation module 1 according to Embodiment 1 of the present invention.

FIG. 1B is a schematic connection diagram schematically showing the connection relationship between the photovoltaic power generation elements 10 and the extension wiring 20 in the photovoltaic power generation module 1 shown in FIG. 1A.

The photovoltaic power generation module 1 according to the present embodiment includes a plurality of photovoltaic power generation elements 10 (namely, for example, photovoltaic power generation elements 11 to 14, . . . , photovoltaic power generation elements 15 to 18) that are arranged such that long sides LS of a perimeter of each rectangular element are parallel, and extension wiring 20 (namely, for example, extension wires 21 to 25) extending in a short side direction Xd that is perpendicular to and intersects the long sides LS (in a perpendicular direction) and interconnecting the photovoltaic power generation elements 10 (the photovoltaic power generation element 11, . . . ). The extension wiring 20 (the extension wire 21, . . . ) connects the photovoltaic power generation elements 10 (the photovoltaic power generation element 11, . . . ) in parallel in every specified number of photovoltaic power generation elements.

Accordingly, since the photovoltaic power generation module 1 according to the present invention includes the extension wiring 20 (the extension wire 21 and so on) that is disposed so as to extend in the short side direction Xd intersecting the long sides LS of the photovoltaic power generation elements 10 (the photovoltaic power generation element 11 and so on) and that connects the photovoltaic power generation elements 10 (the photovoltaic power generation element 11 and so on) in parallel in every specified number of photovoltaic power generation elements, the rectangular photovoltaic power generation elements 10 (the photovoltaic power generation element 11 and so on) arranged in parallel in one dimensional direction can be connected in parallel in a state in which the photovoltaic power generation elements 10 are arranged in a distributed manner, and therefore the reduction in the amount of power generation due to a shade is suppressed and power extraction efficiency is improved.

Hereinafter, the photovoltaic power generation element 11, the photovoltaic power generation element 12, and so on may be referred to simply as the photovoltaic power generation elements 10, where it is unnecessary to make a distinction between them. Also, the extension wire 21, the extension wire 22, and so on may be referred to simply as the extension wiring 20 where it is unnecessary to make a distinction between them.

The photovoltaic power generation elements 10 are arranged (formed) in a layout pattern in which the long sides LS of each elongated rectangle are parallel. In the case where the photovoltaic power generation elements 10 are formed (arranged) on a light transmitting insulating substrate disposed on the side illuminated by light, the wiring surface (the surface shown in the diagram) with respect to the perimeter of the elements is the back of the light receiving surface, and therefore the extension wiring 20 will not affect the light receiving characteristics of the photovoltaic power generation elements 10. The photovoltaic power generation elements 10 conform to an elongated cell shape applied to, for example, thin film silicon solar cells, CIGS (Copper Indium Gallium DiSelenide) solar cells, and the like. The photovoltaic power generation elements 10 can also be applied to a crystal substrate solar cell in which the photovoltaic power generation elements 10 are arranged so as to face a light transmitting insulating substrate disposed on the light receiving surface side, or other solar cells.

For example, four photovoltaic power generation elements 10 (the photovoltaic power generation elements 11 to 14) are arranged in parallel in the short side direction Xd (one dimensional direction) and connected to each other in series, whereby a series section 31 (a series section 30) is formed. Likewise, four photovoltaic power generation elements 10 (the photovoltaic power generation elements 15 to 18) located in a remote position are arranged in parallel in the short side direction Xd and connected to each other in series, whereby a series section 32 (the series section 30) is formed. Hereinafter, the series section 31 and the series section 32 may be referred to simply as the series sections 30, where it is unnecessary to make a distinction between them. Other series sections 30 are arranged at the same interval between the series section 31 and the series section 32.

The expression “the extension wiring 20 connects every specified number of photovoltaic power generation elements 10 in parallel” means that the interval at which the photovoltaic power generation elements 10 are connected in parallel is specified by the number of photovoltaic power generation elements 10 arranged in the series section 30, and in the present embodiment, every four photovoltaic power generation elements 10 are connected in parallel. In other words, the photovoltaic power generation element 11 of the series section 31 (the series section 30) having four elements in series is connected in parallel to the first one of the photovoltaic power generation elements 10 of the series section 30 disposed next, and also connected in parallel to the photovoltaic power generation element 15, which is the first photovoltaic power generation element of the nth series section 32.

In the present embodiment, for the sake of facilitating the understanding, a case will be described in which four photovoltaic power generation elements 10 form a series section 30, but it is also possible to form (dispose) a series section 30 having more series stages by connecting more photovoltaic power generation elements 10 in series, and it is also possible to form (dispose) more series sections 30.

The photovoltaic power generation elements 10 each include a first electrode T1 of a first polarity (for example, p type) disposed on a first side in the short side direction Xd and a second electrode T2 of a second polarity (for example, n type) disposed on a second side in the short side direction Xd. Accordingly, in the photovoltaic power generation module 1, the first electrode T1 having the first polarity and the second electrode T2 having the second polarity are disposed along the extension wiring 20, and therefore the photovoltaic power generation elements 10 and the extension wiring 20 can be easily connected.

Connection points of the extension wiring 20 to the first electrodes T1 are shown as first electrode connection points, and connection points of the extension wiring 20 to the second electrodes T2 are shown as second electrode connection points.

The first electrodes T1 and the second electrodes T2 are each extended along the long sides LS. Accordingly, in the photovoltaic power generation module 1, it is possible to easily and reliably connect the extension wiring 20 (the extension wire 21, etc.) and the first electrodes T1, as well as the extension wiring 20 (the extension wire 21, etc.) and the second electrodes T2. It is also possible to easily collect current over a wide range along the long sides LS.

The extension wire 21 is connected to the first electrode T1 of the photovoltaic power generation element 11 and the first electrode T1 of the photovoltaic power generation element 15 so as to connect the first electrode T1 of the photovoltaic power generation element 11 and the first electrode T1 of the photovoltaic power generation element 15 in parallel.

The extension wire 22 is connected to the second electrode T2 of the photovoltaic power generation element 11 and the first electrode T1 of the photovoltaic power generation element 12 so as to connect the photovoltaic power generation element 11 and the photovoltaic power generation element 12 in series, and is connected to the second electrode T2 of the photovoltaic power generation element 15 and the first electrode T1 of the photovoltaic power generation element 16 so as to connect the photovoltaic power generation element 15 and the photovoltaic power generation element 16 in series. Also, the extension wire 22 connects the second electrode T2 of the photovoltaic power generation element 11 and the first electrode T1 of the photovoltaic power generation element 12, and the second electrode T2 of the photovoltaic power generation element 15 and the first electrode T1 of the photovoltaic power generation element 16 in parallel.

The extension wire 23 is connected to the second electrode T2 of the photovoltaic power generation element 12 and the first electrode T1 of the photovoltaic power generation element 13 so as to connect the photovoltaic power generation element 12 and the photovoltaic power generation element 13 in series, and is connected to the second electrode T2 of the photovoltaic power generation element 16 and the first electrode T1 of the photovoltaic power generation element 17 so as to connect photovoltaic power generation element 16 and the photovoltaic power generation element 17 in series. Also, the extension wire 23 connects the second electrode T2 of the photovoltaic power generation element 12 and the first electrode T1 of the photovoltaic power generation element 13, and the second electrode T2 of the photovoltaic power generation element 16 and the first electrode T1 of the photovoltaic power generation element 17 in parallel.

The extension wire 24 is connected to the second electrode T2 of the photovoltaic power generation element 13 and the first electrode T1 of the photovoltaic power generation element 14 so as to connect the photovoltaic power generation element 13 and the photovoltaic power generation element 14 in series, and is connected to the second electrode T2 of the photovoltaic power generation element 17 and the first electrode T1 of the photovoltaic power generation element 18 so as to connect the photovoltaic power generation element 17 and the photovoltaic power generation element 18 in series. Also, the extension wire 24 connects the second electrode T2 of the photovoltaic power generation element 13 and the first electrode T1 of the photovoltaic power generation element 14, and the second electrode T2 of the photovoltaic power generation element 17 and the first electrode T1 of the photovoltaic power generation element 18 in parallel.

The extension wire 25 is connected to the second electrode T2 of the photovoltaic power generation element 14 and the second electrode T2 of the photovoltaic power generation element 18 so as to connect the second electrode T2 of the photovoltaic power generation element 14 and the second electrode T2 of the photovoltaic power generation element 18 in parallel.

Accordingly, the extension wiring 20 connects the photovoltaic power generation element 15 to the photovoltaic power generation element 11 in parallel, connects the photovoltaic power generation element 16 to the photovoltaic power generation element 12 in parallel, connects the photovoltaic power generation element 17 to the photovoltaic power generation element 13 in parallel, and connects the photovoltaic power generation element 18 to the photovoltaic power generation element 14 in parallel. In other words, the extension wiring 20 connects the photovoltaic power generation elements 15 to 18 (the series section 32) to the photovoltaic power generation elements 11 to 14 (the series section 31) in parallel.

The extension wiring 20 connects the photovoltaic power generation elements 11 to 14 in series to form the series section 31 (the series section 30), and connects the photovoltaic power generation elements 15 to 18 in series to form the series section 32 (the series section 30). Also, the extension wiring 20 connects the photovoltaic power generation elements 10 (the photovoltaic power generation elements 11 to 14) of the series section 31 and the photovoltaic power generation elements 10 (the photovoltaic power generation elements 15 to 18) of the series section 32 in parallel, and thus the series stages of the series section 31 are respectively connected to the series stages of the series section 32 in parallel.

As described above, the photovoltaic power generation module 1 includes series sections 30 (the series section 31, the series section 32), in each of which a group of photovoltaic power generation elements 10 (the photovoltaic power generation elements 11 to 14, the photovoltaic power generation elements 15 to 18) are connected in series.

Accordingly, since the photovoltaic power generation module 1 according to the present embodiment includes series sections 30 (the series section 31, the series section 32, . . . ), in each of which a group of photovoltaic power generation elements 10 (the photovoltaic power generation element 11, etc.) are connected in series, a plurality of series sections 30 can be easily formed along the extension wiring 20 (the extension wire 21, etc.), and thus it is possible to easily achieve parallel connections to the series stages in the series sections 30.

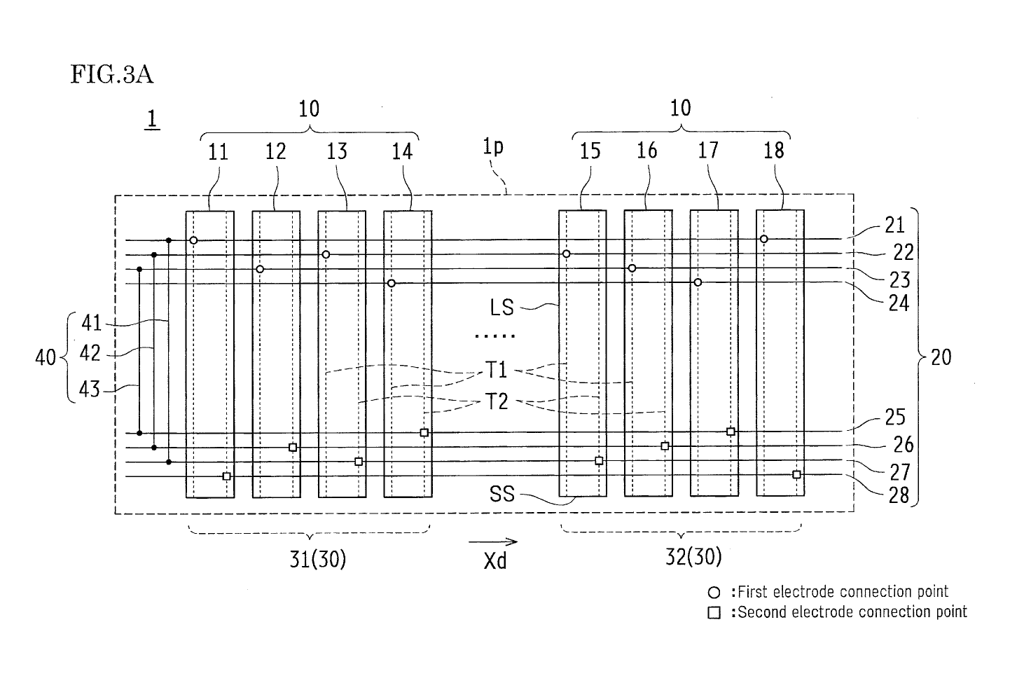

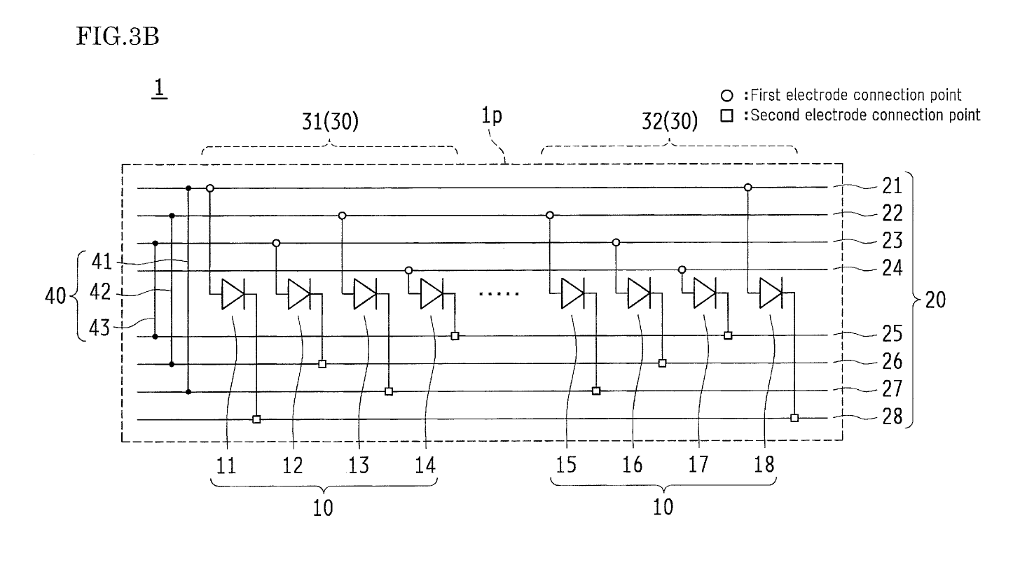

As used herein, “a group of photovoltaic power generation elements 10” refers to a collection of photovoltaic power generation elements 10 (the photovoltaic power generation element 11, etc.) in which a plurality of photovoltaic power generation elements 10 (the photovoltaic power generation element 11, etc.) that are connected in series form a set of series stages according to the series connections. For the sake of facilitating the understanding, FIGS. 1A and 3A show examples using series sections 30 (the series section 31, the series section 32), in each of which four photovoltaic power generation elements 10 (the photovoltaic power generation element 11, etc.) are arranged so as to be adjacent to each other. Also, the photovoltaic power generation elements 10 forming a series section 30 are not necessarily arranged so as to be adjacent to each other, and may be arranged in a distributed manner (see Embodiment 2).

In the photovoltaic power generation module 1, series-parallel connection is used in which n groups of four one-dimensionally arranged and series-connected photovoltaic power generation elements 10 are connected in parallel. The series stages of a series section 30 are connected in parallel to respective series stages of another series section 30 that is connected in parallel to said series section 30.

In other words, in the photovoltaic power generation module 1, a plurality of series sections 30 are connected in parallel by extension wiring 20, each series section 30 including a plurality of photovoltaic power generation elements 10 that are connected in series, and the photovoltaic power generation elements 10 that are connected in the same series stage in the plurality of series sections 30 are connected to each other in parallel by the extension wiring 20. In short, the extension wiring 20 connects every specified number of photovoltaic power generation elements 10 that are arranged spaced apart from each other, and also forms series sections 30.

Note that the extension wiring 20 also connects the photovoltaic power generation elements 10 of other series sections 30 that are not shown, with the same regularity.

As described above, in the photovoltaic power generation module 1, a series section 30 is formed by the photovoltaic power generation elements 10 that are adjacent to each other. With this configuration, in the photovoltaic power generation module 1, a group of photovoltaic power generation elements 10 (the photovoltaic power generation element 11, etc.) that are adjacent to each other are connected in series, whereby a series section 30 (the series section 31, the series section 32) is formed. Accordingly, a plurality of series sections 30 can be easily formed along extension wiring 20.

The photovoltaic power generation elements 10 according to the present embodiment are arranged in a layout pattern in a series section 31 (FIG. 1A), in the order of the photovoltaic power generation element 11, the photovoltaic power generation element 12, the photovoltaic power generation element 13, and the photovoltaic power generation element 14. The photovoltaic power generation elements 10 are also connected such that the arrangement order in the series stages in the series section 31 (FIG. 1B) is the order of the photovoltaic power generation element 11, the photovoltaic power generation element 12, the photovoltaic power generation element 13, and the photovoltaic power generation element 14.

In other words, in the photovoltaic power generation module 1, with respect to the photovoltaic power generation elements 10 of a series section 30, the arrangement order in the series stages in the series section 30 and the arrangement order in the layout pattern in the series section 30 are the same. With this configuration, in the photovoltaic power generation module 1, with respect to the photovoltaic power generation elements 10 of a series section 30, the arrangement order in the series stages in the series section 30 and the arrangement order in the layout pattern in the series section 30 are matched, and therefore parallel connections between a plurality of series sections 30 along extension wiring 20 can be easily achieved with a simple wiring structure. Also, the photovoltaic power generation elements connected in the same series stage are arranged in a distributed manner, and therefore shade resistance can be reliably improved, and a cost reduction can be achieved.

In the photovoltaic power generation module 1 according to the present embodiment, the photovoltaic power generation elements 10 of a series section 30 (the series section 31) that is connected in parallel to another series section 30 (the series section 32) are equidistantly connected in parallel to the photovoltaic power generation elements 10 of the other series section 30 (the series section 32) that are connected in parallel. In other words, the arrangement order of the photovoltaic power generation elements 10 of two series sections 30 that are arranged spaced apart from each other is the same between the two series sections 30.

FIG. 2A is a schematic plan view schematically showing a layout pattern in a photovoltaic power generation module 101 according to a conventional configuration for comparison to illustrate the action of the photovoltaic power generation module 1 shown in FIG. 1A.

The photovoltaic power generation module 101 includes photovoltaic power generation elements 110. The photovoltaic power generation elements 110 are formed and arranged in the same manner as the photovoltaic power generation elements 10 of the photovoltaic power generation module 1.

However, unlike the photovoltaic power generation elements 10, the photovoltaic power generation elements 110 are simply connected in series, and in FIG. 2A, a string of the photovoltaic power generation elements 110 that are continuously connected in series from the left to the right is formed.

For the sake of ease of illustration, series wiring is not shown. The photovoltaic power generation module 101 is integrally mounted on a mounting unit 101p.

The photovoltaic power generation module 101 includes, for example, 280 photovoltaic power generation elements 110 that are connected in series. If it is assumed that each photovoltaic power generation element 110 can provide an output power of 1 V (volt), then, an output power voltage of 280 V can be obtained with 280 elements in series.

FIG. 2B is a schematic diagram of a shade illustrating the state of a shade SH falling on two types of photovoltaic power generation modules that are compared (the photovoltaic power generation module 1 according to the present invention and the photovoltaic power generation module 101 according to a conventional configuration).

The photovoltaic power generation elements 110 of the photovoltaic power generation module 101 have long sides LS and short sides SS that are the same as those of the photovoltaic power generation elements 10 of the photovoltaic power generation module 1, but the wiring state of the photovoltaic power generation elements 10 (FIG. 1A, FIG. 1B) and that of the photovoltaic power generation element 110 (FIG. 2A) are different. As shown in FIGS. 1A and 1B, series wiring and parallel wiring are performed on the photovoltaic power generation elements 10 by the extension wiring 20, whereas the photovoltaic power generation elements 110 of the photovoltaic power generation module 101 are sequentially connected in series from the left to the right.

In other words, the photovoltaic power generation module 101 has an output power voltage of 280 V, with 280 elements in series, whereas the photovoltaic power generation module 1 includes, for example, seven groups in parallel, each group including 40 elements in series (280 photovoltaic power generation elements 10 in total, or in other words, the number of elements is the same as that of the photovoltaic power generation module 101) and thus provides an output power voltage of 40 V. Having seven groups in parallel, the current is 7 times larger than that of the case of 280 elements in series by simple calculation.

Here, as shown in the diagram, it is assumed that a shade SH has, for example, an elongated shape similar to the shape of the photovoltaic power generation elements 10. That is, variations in the output power state are compared assuming an illumination length Lss in the direction of the long sides LS with respect to an effective length Lsc corresponding to the entire length of the long sides LS. In the photovoltaic power generation module 1 according to the present embodiment, the photovoltaic power generation elements 10 have a rectangular shape defined by the long sides LS and the short sides SS, and thus comparison is made assuming that the shade SH has an elongated shape extending along the long sides LS. It is preferable to apply the photovoltaic power generation module 1 to an elongated shade SH from the view point of coping with the reduction of output power, but the present invention is not limited thereto, and the shade may have, for example, a shape that covers the entirety of a series section 30. The comparison result is shown in FIG. 2C.

FIG. 2C is a graph showing the output power characteristics of the two types of photovoltaic power generation modules compared in terms of variations in the output power due to the shade SH.

The horizontal axis indicates the ratio of the illumination length Lss to the effective length Lsc, specifically, indicates the illuminated state by illumination light, which takes a relative value from 0 to 1. The vertical axis indicates the relative output power (a.u.), which takes a relative value from 0 to 1.

The conventional photovoltaic power generation module 101 includes the photovoltaic power generation elements 110 that are simply connected in series, and thus the entire photovoltaic power generation module 101 directly receives the influence of the shade SH. That is, even if the shade SH falls on a single photovoltaic power generation element 110 of the series stages, depending on the condition of the shade SH on the single photovoltaic power generation element 110, the entire module directly receives the influence of the shade, resulting in characteristics following the ratio “effective length Lsc/illumination length Lss” as indicated by a broken line.

In contrast, the photovoltaic power generation elements 10 of the present embodiment are configured into seven groups in parallel, each group including 40 elements in series as described above, and thus the shade SH shown in FIG. 2B affects only one of the seven groups in parallel (a single group in parallel, namely, a single series section 30). Accordingly, even if the ratio “effective length Lsc/effective length Lsc” is 0, it is possible to obtain an output power corresponding to the output power of six groups in parallel, namely, an output power of about 0.86. That is, with the photovoltaic power generation module 1 according to the present embodiment, the reduction of output power due to the shade SH can be reduced significantly, and thus the photovoltaic power generation module 1 can serve as an effective countermeasure against the shade SH.

### Embodiment 2

A photovoltaic power generation module 1 according to the present embodiment will be described with reference to FIGS. 3A and 3B. The basic configuration of the photovoltaic power generation module 1 according to the present embodiment is the same as that of the photovoltaic power generation module 1 according to Embodiment 1, and thus the following description will be given primarily focusing on differences by referring to the reference numerals used in the above embodiment. The photovoltaic power generation module 1 according to the present embodiment is configured such that the arrangement order in the layout pattern of the photovoltaic power generation elements 10 of the series sections 30 and the arrangement order (positions in the series stages) of the photovoltaic power generation elements 10 in the series stages constituted by the series sections 30 are different.

FIG. 3A is a schematic plan view schematically showing the relationship between a layout pattern of photovoltaic power generation elements 10 and extension wiring 20 in a photovoltaic power generation module 1 according to Embodiment 2 of the present invention.

FIG. 3B is a schematic connection diagram schematically showing the connection relationship between the photovoltaic power generation elements 10 and the extension wiring 20 in the photovoltaic power generation module 1 shown in FIG. 3A.

The photovoltaic power generation module 1 according to the present embodiment includes a series section 31, a series section 32, . . . (a series section 30). The series section 31 are formed by photovoltaic power generation elements 11 to 14 that are connected to each other in series, and the series section 32 are formed by photovoltaic power generation elements 15 to 18 that are connected to each other in series. Note that the extension wiring 20 also connects the photovoltaic power generation elements 10 of other series sections 30 that are not shown, with the same regularity.

An extension wire 21 is connected to the first electrode T1 of the photovoltaic power generation element 11 and the first electrode T1 of the photovoltaic power generation element 18 so as to connect the first electrode T1 of the photovoltaic power generation element 11 and the first electrode T1 of the photovoltaic power generation element 18 in parallel.

An extension wire 22 is connected to the first electrode T1 of the photovoltaic power generation element 13 and the first electrode T1 of the photovoltaic power generation element 15 so as to connect the first electrode T1 of the photovoltaic power generation element 13 and the first electrode T1 of the photovoltaic power generation element 15 in parallel.

An extension wire 23 is connected to the first electrode T1 of the photovoltaic power generation element 12 and the first electrode T1 of the photovoltaic power generation element 16 so as to connect the first electrode T1 of the photovoltaic power generation element 12 and the first electrode T1 of the photovoltaic power generation element 16 in parallel.

An extension wire 24 is connected to the first electrode T1 of the photovoltaic power generation element 14 and the first electrode T1 of the photovoltaic power generation element 17 so as to connect the first electrode T1 of the photovoltaic power generation element 14 and the first electrode T1 of the photovoltaic power generation element 17 in parallel.

An extension wire 25 is connected to the second electrode T2 of the photovoltaic power generation element 14 and the second electrode T2 of the photovoltaic power generation element 17 so as to connect the second electrode T2 of the photovoltaic power generation element 14 and the second electrode T2 of the photovoltaic power generation element 17 in parallel.

An extension wire 26 is connected to the second electrode T2 of the photovoltaic power generation element 12 and the second electrode T2 of the photovoltaic power generation element 16 so as to connect the second electrode T2 of the photovoltaic power generation element 12 and the second electrode T2 of the photovoltaic power generation element 16 in parallel.

An extension wire 27 is connected to the second electrode T2 of the photovoltaic power generation element 13 and the second electrode T2 of the photovoltaic power generation element 15 so as to connect the second electrode T2 of the photovoltaic power generation element 13 and the second electrode T2 of the photovoltaic power generation element 15 in parallel.

An extension wire 28 is connected to the second electrode T2 of the photovoltaic power generation element 11 and the second electrode T2 of the photovoltaic power generation element 18 so as to connect the second electrode T2 of the photovoltaic power generation element 11 and the second electrode T2 of the photovoltaic power generation element 18 in parallel.

Accordingly, as will be shown next, the extension wiring 20 connects in parallel the photovoltaic power generation elements 11 to 14 of the series section 31 and the photovoltaic power generation elements 15 to 18 of the series section 32 in corresponding series stages.

The extension wire 21 and the extension wire 28 connect in parallel the photovoltaic power generation element 11 and the photovoltaic power generation element 18 in every specified number of photovoltaic power generation elements. The photovoltaic power generation element 11 is disposed as the first one (first stage) in the series section 31 (the series section 30), and the photovoltaic power generation element 18 is disposed as the fourth one (fourth stage) in the series section 32 (the series section 30).

The extension wire 22 and the extension wire 27 connect in parallel the photovoltaic power generation element 13 and the photovoltaic power generation element 15 in every specified number of photovoltaic power generation elements. The photovoltaic power generation element 13 is disposed as the third one in the series section 31, and the photovoltaic power generation element 15 is disposed as the first one in the series section 32.

The extension wire 23 and the extension wire 26 connect in parallel the photovoltaic power generation element 12 and the photovoltaic power generation element 16 in every specified number of photovoltaic power generation elements. The photovoltaic power generation element 12 is disposed as the second one in the series section 31, and the photovoltaic power generation element 16 is disposed as the second one in the series section 32.

The extension wire 24 and the extension wire 25 connect in parallel the photovoltaic power generation element 14 and the photovoltaic power generation element 17 in every specified number of photovoltaic power generation elements. The photovoltaic power generation element 14 is disposed as the fourth one in the series section 31, and the photovoltaic power generation element 17 is disposed as the third one in the series section 32.

Also, the photovoltaic power generation module 1 according to the present embodiment includes, in addition to the extension wiring 20, cross wiring 40 (a cross wire 41, a cross wire 42, and a cross wire 43). The cross wire 41 connects the extension wire 21 and the extension wire 27. The cross wire 42 connects the extension wire 22 and the extension wire 26. The cross wire 43 connects the extension wire 23 and the extension wire 25. Hereinafter, the cross wire 41, the cross wire 42, and the cross wire 43 may be referred to simply as the cross wiring 40, where it is unnecessary to make a distinction between them.

In other words, the extension wiring 20 is interconnected by the cross wiring 40, and the connection order (the arrangement order in the series stages, or in other words, current path) in the series stages in the series sections 30 is defined by the connection state of the cross wiring 40.

The current path (the arrangement order in the series stages) in the series section 31 is, when indicated by the forward direction of the diode symbols shown in the diagram for the sake of facilitating the understanding, the extension wire 24→the photovoltaic power generation element 14 (the fourth one from the left of the layout pattern shown in the diagram)→the extension wire 25→the cross wire 43→the extension wire 23→the photovoltaic power generation element 12 (the second one of the same)→the extension wire 26→the cross wire 42→photovoltaic power generation element 13 (the third one of the same)→the extension wire 27→the cross wire 41→the extension wire 21→the photovoltaic power generation element 11 (the first one of the same)→the extension wire 28.

The current path (the arrangement order in the series stages) in the series section 32 is, when indicated by the forward direction of the diode symbols shown in the diagram for the sake of facilitating the understanding, the extension wire 24→the photovoltaic power generation element 17 (the third one from the left of the layout pattern shown in the diagram)→the extension wire 25→the cross wire 43→the extension wire 23→the photovoltaic power generation element 16 (the second one in the layout pattern)→the extension wire 26→the cross wire 42→the photovoltaic power generation element 15 (the first one in the layout pattern)→the extension wire 27→the cross wire 41→the extension wire 21→the photovoltaic power generation element 18 (the fourth one in the layout pattern)→the extension wire 28.

The arrangement order in the series stages in the series section 31 is the fourth one, the second one, the third one, and the first one in the arrangement order in the layout pattern, whereas in the series section 32, the arrangement order in the series stages is the third one, the second one, the first one, and the fourth one in the arrangement order in the layout pattern.

In other words, in the photovoltaic power generation module 1 according to the present embodiment, with respect to the photovoltaic power generation elements 10 (the photovoltaic power generation element 11, etc.) of the series sections 30, the arrangement order in the series stages in the series sections 30 (the series section 31, the series section 32) and the arrangement order in the layout pattern in the series sections 30 (the series section 31, the series section 32) are different.

Accordingly, in the photovoltaic power generation module 1 according to the present embodiment, with respect to the photovoltaic power generation elements 10 arranged in the series sections 30, the arrangement order in the series stages in the series sections 30 and the arrangement order in the layout pattern in the series sections 30 are made different, and therefore the photovoltaic power generation elements 10 are arranged with a further improved degree of distribution of the photovoltaic power generation elements 10 that are connected in the same series stage, as a result of which shade resistance is further improved.

Also, the photovoltaic power generation module 1 according to the present embodiment includes the cross wiring 40 that interconnects the extension wiring 20. With this configuration, the photovoltaic power generation module 1 includes the cross wiring 40 (the cross wire 41, etc.) that interconnects the extension wiring 20 (the extension wire 21, etc.), and therefore the arrangement order in the series stages of the photovoltaic power generation elements 10 in the series sections 30 can be freely set by forming a current path between wires of the extension wiring 20 (the extension wire 21, etc.), as a result of which the degree of distribution of the photovoltaic power generation elements 10 can be improved easily and reliably. Accordingly, the shade resistance of the photovoltaic power generation module 1 is further improved.

In the photovoltaic power generation module 1 according to the present embodiment, the photovoltaic power generation elements 10 of a series section 30 connected in parallel to another series section 30 are connected in parallel to the photovoltaic power generation elements 10 that are connected in parallel in the other series section 30, at different intervals. In other words, the arrangement order of the photovoltaic power generation elements 10 in the series sections 30 that are arranged spaced apart from each other is different among the series sections 30.

### Embodiment 3

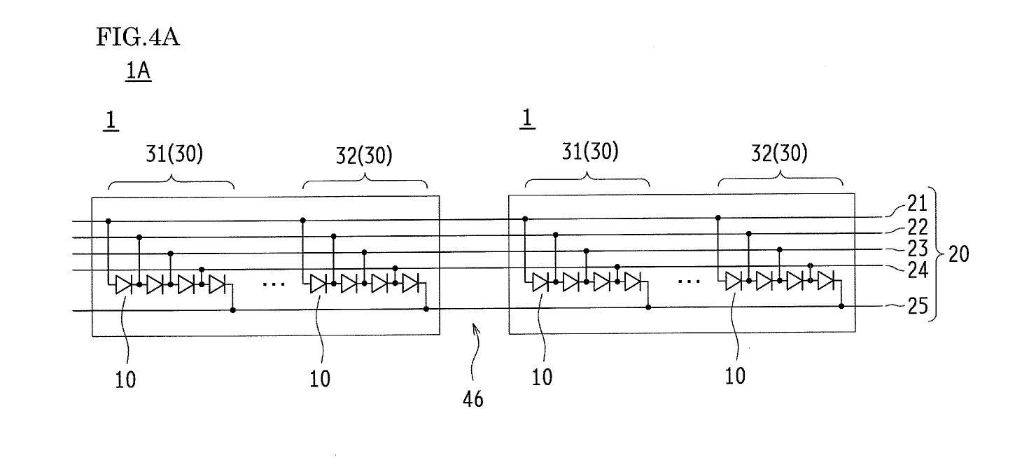

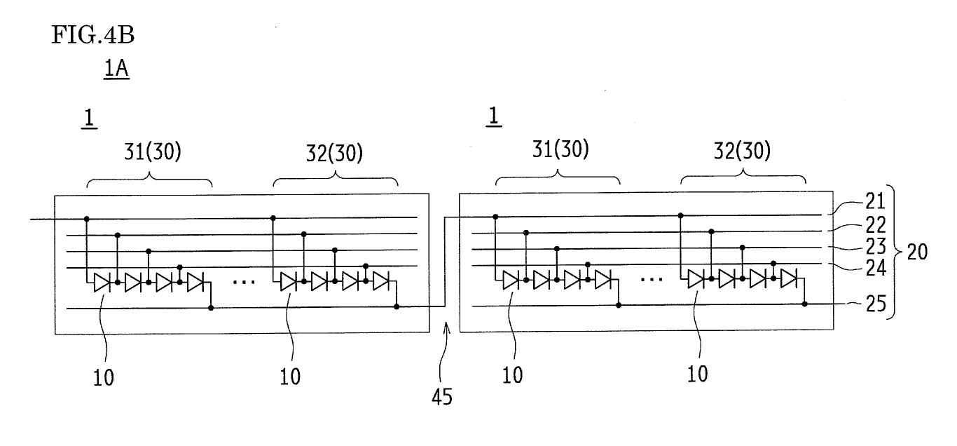

A photovoltaic power generation module array 1A according to the present embodiment will be described with reference to FIGS. 4A and 4B. The photovoltaic power generation module array 1A according to the present embodiment is a photovoltaic power generation module array in which a plurality of the photovoltaic power generation modules 1 (the photovoltaic power generation elements 10, the series sections 30) according to Embodiment 1 or 2 are connected. The basic configuration thereof is as described above in Embodiments 1 and 2, and thus the following description will be given primarily focusing on differences by referring to the reference numerals used in the above embodiments.

FIG. 4A is a schematic plan view schematically showing a connection state (parallel connection) of photovoltaic power generation modules 1 in a photovoltaic power generation module array 1A according to Embodiment 3 of the present invention.

The photovoltaic power generation module array 1A includes a plurality of photovoltaic power generation modules 1 that are connected to each other. The photovoltaic power generation module 1 is as described above in Embodiments 1 and 2. Accordingly, the photovoltaic power generation module array 1A according to the present embodiment includes a plurality of the photovoltaic power generation modules 1 of the present invention, and therefore a large amount of photovoltaic power generation with excellent shade resistance and good power extraction efficiency is possible.

In the photovoltaic power generation module array 1A (FIG. 4A), the photovoltaic power generation modules 1 are connected in parallel via parallel wiring 46 disposed (connecting) between modules. Accordingly, because the photovoltaic power generation modules 1 are connected in parallel, the photovoltaic power generation module array 1A can generate a large current while shade resistance is improved.

The parallel wiring 46 is configured to interconnect the extension wiring 20 in parallel.

FIG. 4B is a schematic plan view schematically showing a connection state (series connection) of photovoltaic power generation modules 1 in a photovoltaic power generation module array 1A according to Embodiment 3 of the present invention.

In the photovoltaic power generation module array 1A shown in FIG. 4A, because the photovoltaic power generation modules 1 are connected in parallel, a situation can occur in which the current capacity becomes large. Accordingly, a large current flows through a connection section (power cable section), and therefore a resistance loss caused by the large current may occur. In the case where it is necessary to avoid the resistance loss, as shown in FIG. 4B, the photovoltaic power generation modules 1 can be connected in series. The basic configuration is as shown in FIG. 4A, and thus the following description will be given primarily focusing on differences.

In the photovoltaic power generation module array 1A (FIG. 4B), the photovoltaic power generation modules 1 are connected in series via series wiring 45 disposed (connecting) between modules. Accordingly, because the photovoltaic power generation modules 1 are connected in series, the photovoltaic power generation module array 1A can generate a high voltage while shade resistance is improved. Also, the current can be lowered due to the high voltage, and therefore the resistance loss in the current path can be reduced.

The series wiring 45 is configured to join the entire photovoltaic power generation modules 1 together and connect to the next photovoltaic power generation module 1.

### Embodiment 4

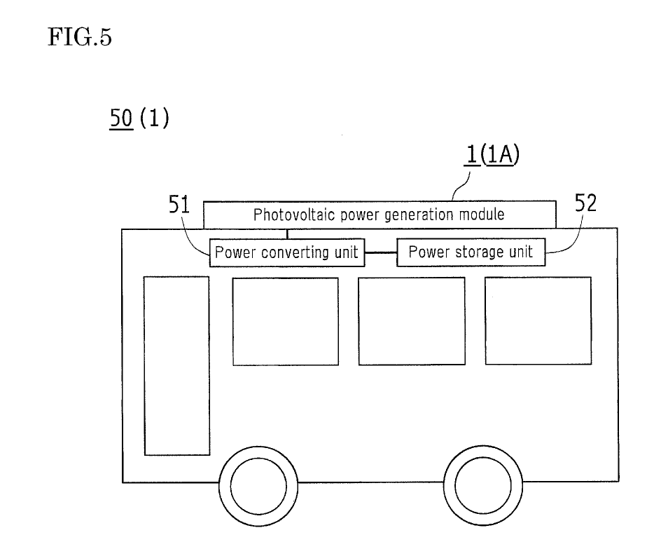

A mobile unit 50 according to the present embodiment will be described with reference to FIG. 5. The mobile unit 50 according to the present embodiment is a mobile unit including the photovoltaic power generation module 1 described in Embodiment 1 or the photovoltaic power generation module array 1A described in Embodiment 3. The basic configuration is as described above in Embodiment 1 or 3, and thus the following description will be given primarily focusing on differences by referring to the reference numerals used in the above embodiments.

FIG. 5 is a schematic diagram schematically showing the overall view of a mobile unit 50 according to Embodiment 4 of the present invention.

The mobile unit 50 according to the present embodiment incorporates a photovoltaic power generation module 1 (or a photovoltaic power generation module array 1A) in which a plurality of photovoltaic power generation elements 10 are connected. In other words, the mobile unit 50 includes a photovoltaic power generation module 1 (or a photovoltaic power generation module array 1A) according to Embodiment 1 or 3.

The power generated by photovoltaic power generation in the photovoltaic power generation module 1 is transmitted to a power converting unit 51, subjected to an appropriate power conversion, and then stored in, for example, a power storage unit 52. Alternatively, the power is transmitted to an unshown load (for example, motor) and consumed.

With the mobile unit 50, the state of the shade SH varies with time according to the moving condition of the mobile unit 50, and thus it is not possible to receive a constant amount of illumination light (sunlight) in a stable manner while the mobile unit is traveling. However, the mobile unit 50 incorporates the photovoltaic power generation module 1 according to Embodiment 1 or the photovoltaic power generation module array 1A according to Embodiment 3, and therefore the reduction in the amount of power generation due to the shade SH can be prevented. Accordingly, a stable amount of power can be obtained by the photovoltaic power generation module 1 incorporated in the mobile unit, and it is therefore possible to achieve highly reliable and stable movement while securing the power obtained by photovoltaic power generation.

The present invention can be embodied in various other forms without departing from the gist or essential characteristics thereof. Therefore, the embodiments described above are to be considered in all respects as illustrative and not limiting. The scope of the invention is indicated by the appended claims rather than by the foregoing description. Furthermore, all modifications or changes that come within the meaning and range of equivalency of the claims are intended to be embraced therein.

What is claimed is:

1. A photovoltaic power generation module comprising:
a plurality of rectangular photovoltaic power generation elements that are arranged such that long sides of perimeters of the elements are parallel; and
an extension wiring that is extended in a short side direction intersecting the long sides and that interconnects the photovoltaic power generation elements,
wherein the extension wiring connects every specified number of the photovoltaic power generation elements in parallel.

2. The photovoltaic power generation module according to claim 1,
wherein the photovoltaic power generation elements comprise a first electrode of a first polarity that is disposed on a first side in the short side direction and a second electrode of a second polarity that is disposed on a second side in the short side direction.

3. The photovoltaic power generation module according to claim 2,
wherein the first electrode and the second electrode are extended along the long sides respectively.

4. The photovoltaic power generation module according to claim 1, comprising
a series section in which a group of the photovoltaic power generation elements are connected in series.

5. The photovoltaic power generation module according to claim 4,
wherein the series section is formed by the photovoltaic power generation elements that are adjacent to each other.

6. The photovoltaic power generation module according to claim 5,
wherein with respect to the photovoltaic power generation elements arranged in the series section, an arrangement order in series stages in the series section and an arrangement order in a layout pattern in the series section are the same.

7. The photovoltaic power generation module according to claim 5,
wherein with respect to the photovoltaic power generation elements arranged in the series section, an arrangement order in series stages in the series section and an arrangement order in a layout pattern in the series section are different.

8. The photovoltaic power generation module according to claim 7, comprising
a cross wiring that interconnects the extension wiring mutually.

9. A photovoltaic power generation module array comprising
a plurality of photovoltaic power generation modules,
wherein the photovoltaic power generation modules are photovoltaic power generation modules according to claim 1.

10. The photovoltaic power generation module array according to claim 9,
wherein the photovoltaic power generation modules are connected in parallel.

11. The photovoltaic power generation module array according to claim 10,
wherein the photovoltaic power generation modules are connected in series.

12. A mobile unit comprising a photovoltaic power generation module in which a plurality of photovoltaic power generation elements are connected,
wherein the photovoltaic power generation module is a photovoltaic power generation module according to claim 1.
